(19) United States
(12) Patent Application Publication
(10) Pub. No.: US 2025/0271993 A1
(43) Pub. Date: Aug. 28, 2025

(54) NONVOLATILE MEMORY DEVICE, METHOD OF OPERATING THE SAME, AND MEMORY SYSTEM INCLUDING THE SAME

(71) Applicant: Samsung Electronics Co., Ltd., Suwon-si (KR)

(72) Inventors: Hyun-Ju KIM, Suwon-si (KR); Dukyoung YUN, Suwon-si (KR); Ju-Young LEE, Suwon-si (KR)

(73) Assignee: Samsung Electronics Co., Ltd., Suwon-si (KR)

(21) Appl. No.: 19/006,526

(22) Filed: Dec. 31, 2024

(30) Foreign Application Priority Data
Feb. 27, 2024 (KR) 10-2024-0028052

(51) Int. Cl. G06F 3/06

(52) U.S. Cl. CPC G06F 3/061; G06F 3/0659; G06F 3/0679

(57) ABSTRACT

A nonvolatile memory device may include processing circuitry configured to receive a read command, a start read address, and a data chunk indicator, the read command including a page read command and a data read command, and the start read address including a start row address and a start column address, a memory cell array configured to output first page data based on the start row address, the first page data including a plurality of first data chunks, and the processing circuitry further configured to output one or more of the plurality of first data chunks based on the data chunk indicator.

### CROSS-REFERENCE TO RELATED APPLICATION

This U.S. non-provisional application claims the benefit of priority under 35 U.S.C. § 119 to Korean Patent Application No. 10-2024-0028052 filed on Feb. 27, 2024, in the Korean Intellectual Property Office, the disclosure of which is incorporated by reference herein in its entirety.

### BACKGROUND

Various example embodiments of the inventive concepts described herein relate to a semiconductor device, and more particularly, relate to a nonvolatile memory device, an operating method of the nonvolatile memory device, and/or a memory system including the nonvolatile memory device, etc.

Electronic devices which include a plurality of memory systems including nonvolatile memory devices are widely used. Such memory systems support stability and durability, fast access speed of information, and consume less power.

The nonvolatile memory device may include a memory cell array, a page buffer circuit, and a data input/output circuit. In the process of reading data stored in the memory cell array, the memory cell array may output page data to the page buffer circuit, and the page buffer circuit may output a part of or all of the page data to the data input/output circuit. When the page buffer circuit outputs a part of the page data, more commands may be desired and/or required depending on the structure of the page buffer circuit in which the part of the page data is stored. In electronic devices including a plurality of nonvolatile memory devices, increases in the number of commands may create a bottleneck in an interface circuit, which may act as an overhead of the interface circuit and may degrade input/output performance of the nonvolatile memory device, decrease the access speed of the information, increase the power consumption of the electronic device, etc.

### SUMMARY

One or more example embodiments of the inventive concepts provide a nonvolatile memory device which improves input/output performance.

One or more example embodiments of the inventive concepts provide an operating method of a nonvolatile memory device.

One or more example embodiments of the inventive concepts provide a memory system which includes a nonvolatile memory device.

According to at least one example embodiment, a nonvolatile memory device includes processing circuitry configured to receive a read command, a start read address, and a data chunk indicator, the read command including a page read command and a data read command, and the start read address including a start row address and a start column address, a memory cell array configured to output first page data based on the start row address, the first page data including a plurality of first data chunks, and the processing circuitry further configured to output one or more of the plurality of first data chunks based on the data chunk indicator.

According to at least one example embodiment, an operating method of a nonvolatile memory device may include receiving a read command, a start read address, and a data chunk indicator, the read command including a page read command and a data read command, and the start read address including a start row address and a start column address, outputting first page data based on the start row address, the first page data including a plurality of first data chunks, and outputting one or more of the plurality of first data chunks based on the data chunk indicator.

According to at least one example embodiment, a memory system includes a memory controller configured to output a read command, a start read address, and a data chunk indicator, the read command including a page read command and a data read command, and the start read address including a start row address and a start column address, and a nonvolatile memory device configured to operate based on the read command, the start read address, and the data chunk indicator, the nonvolatile memory device including, a memory cell array configured to output first page data based on the start row address, the first page data including a plurality of first data chunks, and a page buffer circuit configured to continuously output two or more of the plurality of first data chunks based on the data chunk indicator.

### BRIEF DESCRIPTION OF THE FIGURES

The above and other objects and/or features of the example embodiments of the inventive concepts will become apparent by describing in detail some example embodiments thereof with reference to the accompanying drawings.

FIG. 1 is a block diagram illustrating a memory system including a nonvolatile memory device according to at least one example embodiment of the inventive concepts.

FIG. 2 is a diagram explaining planes, blocks, and pages included in a memory cell array of FIG. 1 according to at least one example embodiment.

FIG. 3 is a diagram explaining a start read address and a data chunk indicator of FIG. 1 according to at least one example embodiment.

FIG. 4 is a diagram explaining one or more of a plurality of first data chunks output from a page buffer circuit of FIG. 1 based on a data chunk indicator according to at least one example embodiment.

FIG. 5 is a flowchart illustrating an operating method of a nonvolatile memory device according to at least one example embodiment of the inventive concepts.

FIG. 6 is a block diagram illustrating data and other control signals between a nonvolatile memory device of FIG. 1 and a memory controller communicating therewith according to at least one example embodiment.

FIG. 7 is a block diagram illustrating at least one example embodiment of a nonvolatile memory device of FIG. 1.

FIG. 8 is a timing diagram explaining at least one example embodiment of an operation of the nonvolatile memory device of FIG. 1, FIG. 6, or FIG. 7.

FIG. 9 is a flowchart explaining an operation in which a control circuit of FIG. 7 receives a read command, a start read address, and a data chunk indicator according to at least one example embodiment.

FIG. 10 is a flowchart illustrating at least one example embodiment of an operation in which a control circuit of FIG. 7 receives a read command and a start read address.

FIG. 11 is a flowchart illustrating at least one example embodiment of an operation in which a control circuit of FIG. 7 receives a read command and a data chunk indicator.

FIG. 12A and FIG. 12B are diagrams illustrating at least one example embodiment of a data chunk indicator of FIG. 1.

FIG. 13 is a flowchart illustrating at least one example embodiment of an operation in which a control circuit of FIG. 7 outputs one or more of a plurality of first data chunks.

FIG. 14 is a timing diagram explaining at least one example embodiment of an operation of the nonvolatile memory device of FIG. 7.

FIG. 15 is a block diagram illustrating at least one example embodiment of a memory controller communicating with a nonvolatile memory device of FIG. 1.

FIG. 16 is a flowchart illustrating an operating method of a nonvolatile memory device according to at least one example embodiment of the inventive concepts.

FIG. 17 is a block diagram illustrating a data center including another nonvolatile memory device according to at least one example embodiment of the inventive concepts.

### DETAILED DESCRIPTION

Hereinafter, various example embodiments of the inventive concepts will be described clearly and in detail so that a person of ordinary skill in the technical field of the inventive concepts may practice the example embodiments of the inventive concepts.

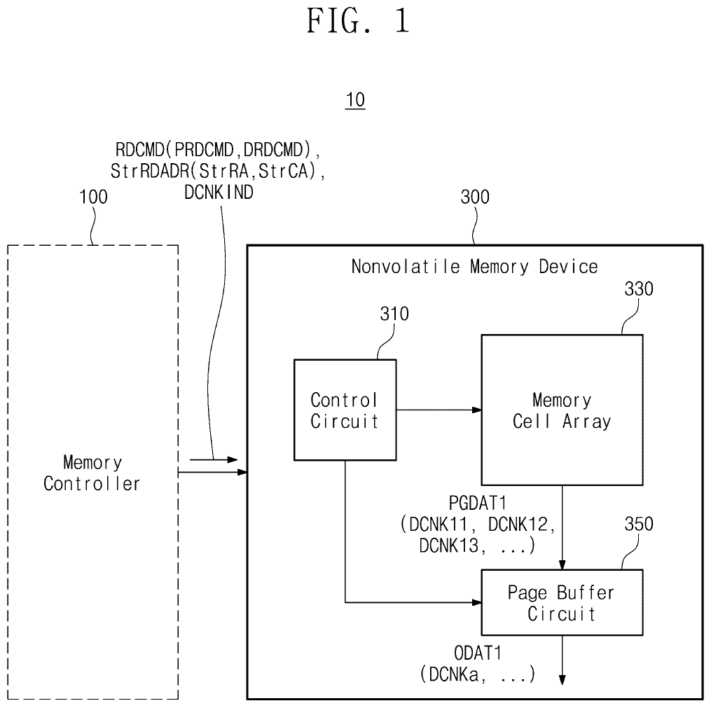

FIG. 1 is a block diagram illustrating a memory system including a nonvolatile memory device according to at least one example embodiment of the inventive concepts.

Referring to FIG. 1, a memory system 10 may include a memory controller 100 and a nonvolatile memory device 300. The nonvolatile memory device 300 may include a control circuit 310, a memory cell array 330, and/or a page buffer circuit 350, etc., but is not limited thereto and for example, the memory system 10 may include a greater or lesser number of constituent components. According to some example embodiments, one or more of the memory controller 100, the control circuit 310, and/or the page buffer circuit 350, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The memory controller 100 may generally control operations of the nonvolatile memory device 300, but is not limited thereto. For example, the memory controller 100 may store data in the memory cell array 330 of the nonvolatile memory device 300, may read data stored in the memory cell array 330, and/or erase data stored in the memory cell array 330, etc. The storing of data, the reading of data, and/or the erasing of data may be initiated by an external host device and/or by the memory controller 100 itself.

The control circuit 310 may generally control operations of the memory cell array 330 and/or the page buffer circuit 350, etc. For example, the memory cell array 330 may include a plurality of memory cells which store data, and the page buffer circuit 350 may include a plurality of latches which temporarily store data provided from the memory cell array 330 and/or the memory controller 100, etc. The control circuit 310 may control the memory cells and the latches to perform the storing, reading, and/or erasing of data, etc.

When the memory controller 100 attempts to read specific data (hereinafter referred to as “target data”) stored in specific memory cells (hereinafter referred to as “target memory cells”) of the memory cell array 330, a read command RDCMD, a start read address StrRDADR, and/or a data chunk indicator DCNKIND are generated, and the read command RDCMD, the start read address StrRDADR, and/or the data chunk indicator DCNKIND may be issued (and/or output, etc.) to the nonvolatile memory device 300.

The nonvolatile memory device 300 may receive the read command RDCMD, the start read address StrRDADR, and/or the data chunk indicator DCNKIND from the memory controller 100, and may provide the target data to the memory controller 100 based on the read command RDCMD, the start read address StrRDADR, and/or the data chunk indicator DCNKIND.

In at least one example embodiment, the read command RDCMD may include a page read command PRDCMD and a data read command DRDCMD, and the start read address StrRDADR may include a start row address StrRA and a start column address StrCA, but the example embodiments are not limited thereto. The page read command PRDCMD may be a command for outputting page data stored in one page of the memory cell array 330 from the memory cell array 330 to the page buffer circuit 350, and the data read command DRDCMD may be a command for outputting some or all of the page data from the page buffer circuit 350 to a data input/output circuit (not illustrated).

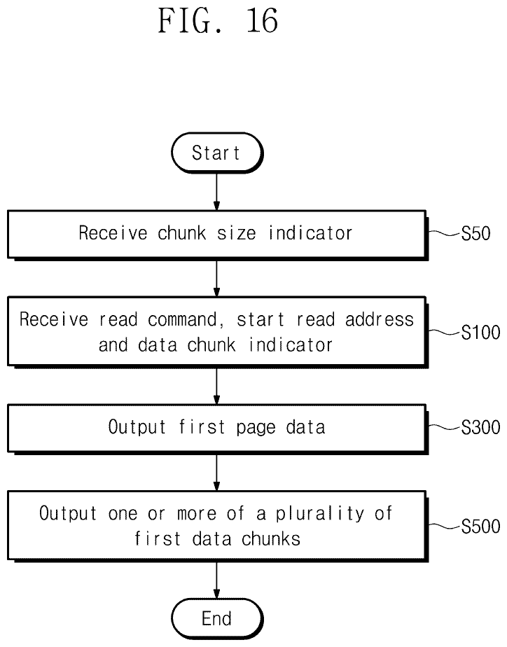

In at least one example embodiment, some or all of the output of the page data based on the data read command DRDCMD may be performed in units of data chunk (e.g., data chunk units, etc.). For example, one data chunk unit may be a set of data defined by dividing the page data evenly or unevenly (e.g., the size of a page of data may be evenly divisible by the size of a data chunk unit, or the size of a page of data may be unevenly divisible by the size of a data chunk unit), and the data chunk indicator DCNKIND may individually indicate each of the data chunks which are some or all of the page data and may be output from the page buffer circuit 350. In other words, the size of one data chunk may be smaller than or equal to the size of a page of data. Further, the size of one data chunk may be variable and/or configurable, and may be defined and/or set using the data chunk indicator and/or a chunk size indicator to be discussed in greater detail in connection with FIG. 16. Moreover, the size of one data chunk may be dynamically defined and/or dynamically set by a host device (e.g., an external device, etc.), the control circuit 310, and/or the memory controller 100, etc., using the data chunk indicator and/or a chunk size indicator, but the example embodiments are not limited thereto.

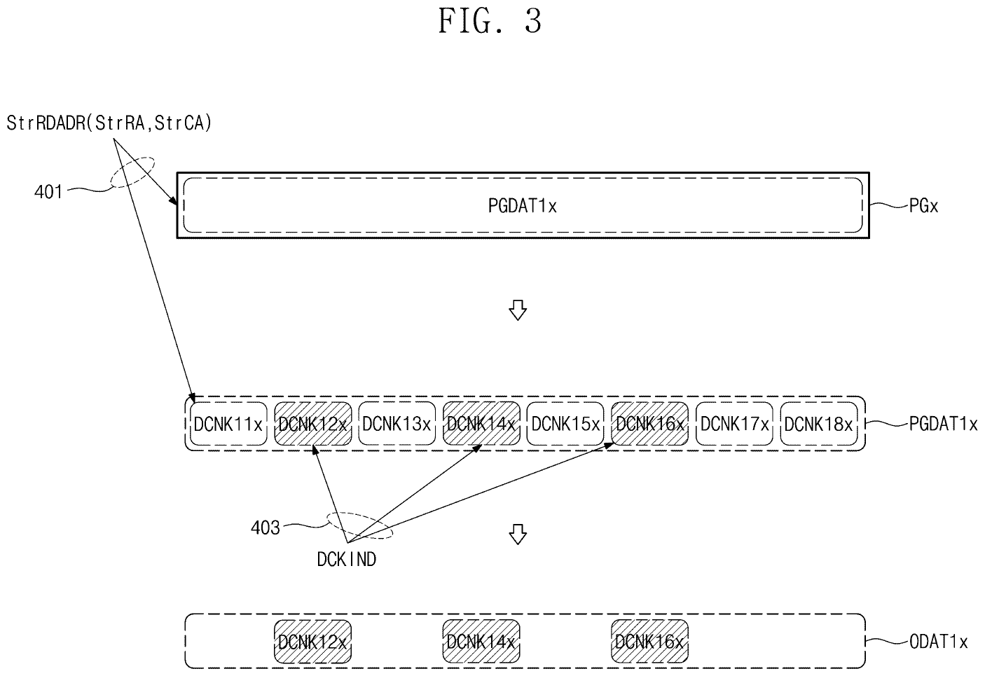

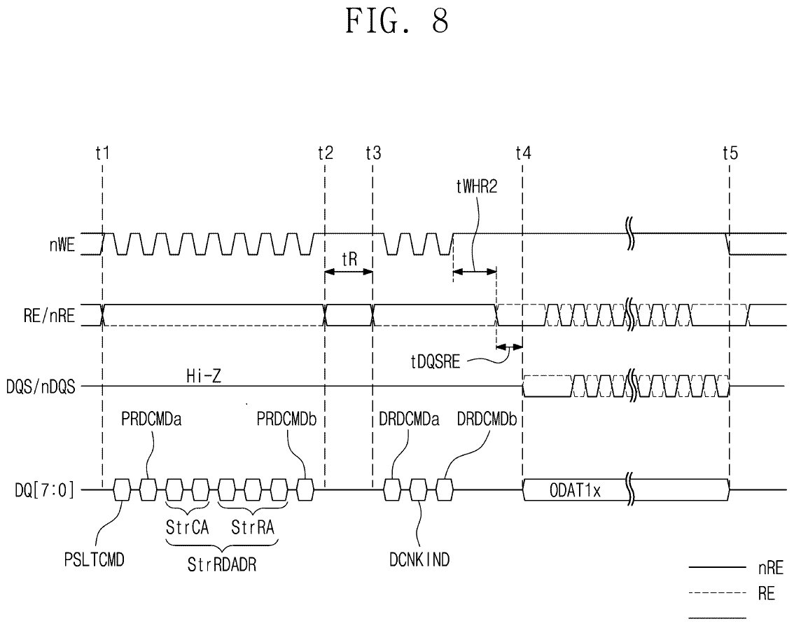

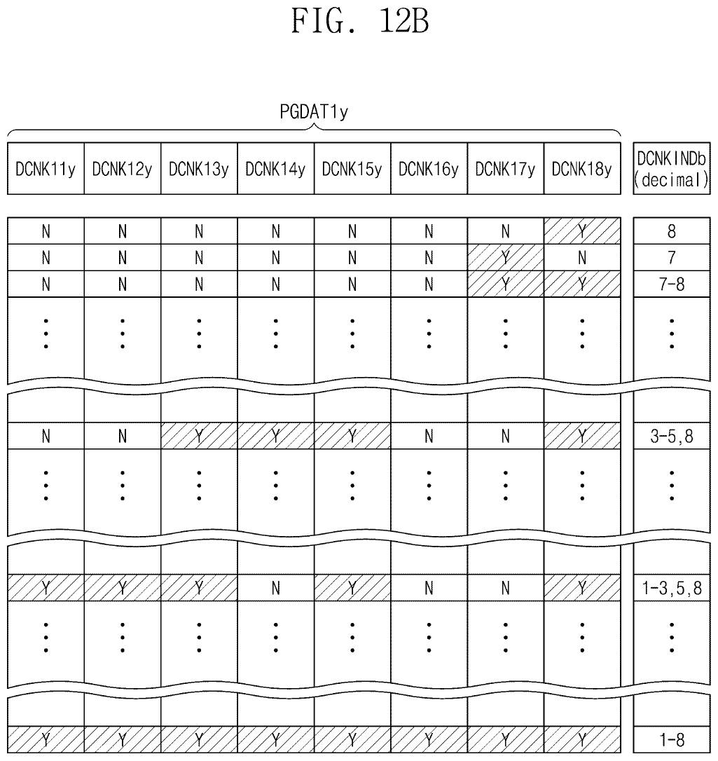

In at least one example embodiment, the start row address StrRA and the start column address StrCA may indicate the page data output from the memory cell array 330 to the page buffer circuit 350, and a location indicated by the start row address StrRA and the start column address StrCA may be a reference for the data chunk indicator DCNKIND to individually indicate and/or specify each of the data chunks. The read command RDCMD, the start read address StrRDADR, and the data chunk indicator DCNKIND will be described in greater detail with reference to FIG. 3, FIG. 8, FIG. 12A, and FIG. 12B.

In at least one example embodiment, the control circuit 310 receives the read command RDCMD, the start read address StrRDADR, and/or the data chunk indicator DCNKIND from the memory controller 100, and may control the memory cell array 330 and the page buffer circuit 350, respectively, based on the read command RDCMD, the start read address StrRDADR, and/or the data chunk indicator DCNKIND, etc. The memory cell array 330 may output first page data PGDAT1 including a plurality of first data chunks DCNK11, DCNK12, DCNK13, and the like to the page buffer circuit 350 based on the start row address StrRA. The page buffer circuit 350 may generate and/or transmit output data ODAT1 including one or more of the plurality of first data chunks DCNK11, DCNK12, DCNK13, and the like to the data input/output circuit based on the data chunk indicator DCNKIND, but the example embodiments are not limited thereto.

In at least one example embodiment, the first page data PGDAT1 may correspond to the start row address StrRA and may be data stored in memory cells arranged in one row of the memory cell array 330, but is not limited thereto.

In at least one example embodiment, although the first page data PGDAT1 includes the plurality of first data chunks, e.g., DCNK11, DCNK12, DCNK13, and the like, the memory cell array 330 only outputs the page data stored in the memory cells arranged in one row of the memory cell array 330, and therefore, the memory cell array may not output the first page data PGDAT1 in units of data chunk, but the example embodiments are not limited thereto. For example, in some example embodiments of the inventive concepts, the memory cell array 330 may perform normal operations of a conventional memory cell array, but is not limited thereto.

According to at least one example embodiment, data chunks (e.g., DCNKa, . . . ) output from the page buffer circuit 350 may correspond to a plurality of read address ranges. The plurality of read address ranges may represent addresses of the target memory cells of the memory cell array 330 and may be determined by the host device and/or the memory controller 100 to start reading the target data, but is not limited thereto.

In at least one example embodiment, the plurality of read address ranges may be continuous (e.g., sequential) or discontinuous (e.g., non-sequential) in an address space of the memory cell array 330. When the plurality of read address ranges are continuous (e.g., sequential, etc.), the data chunks output from the page buffer circuit 350 may be stored in continuous latches of the page buffer circuit 350 (e.g., may be continuously stored, etc.), and when the plurality of read address ranges are discontinuous, the data chunks output from the page buffer circuit 350 may be stored in discontinuous latches of the page buffer circuit 350 (e.g., may be stored discontinuously, etc.).

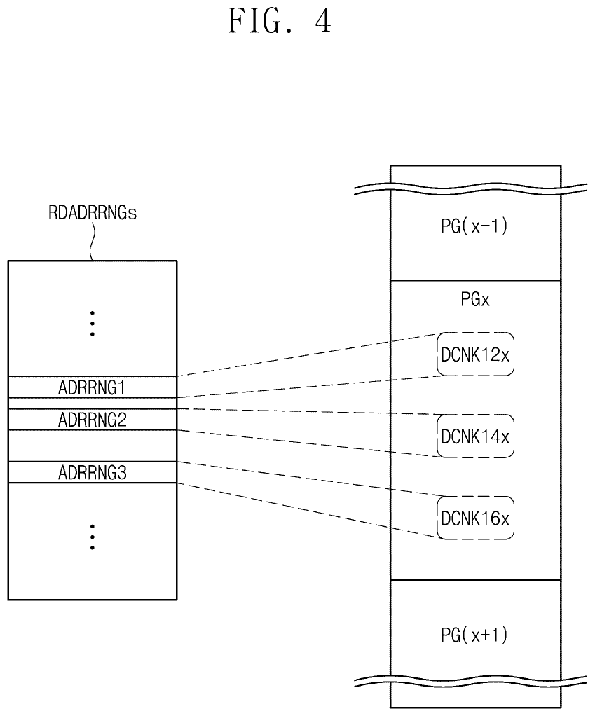

In at least one example embodiment, the page buffer circuit 350 may output and/or continuously output two or more of the plurality of first data chunks DCNK11, DCNK12, DCNK13, and the like, which are indicated by the data chunk indicator DCNKIND. For example, the page buffer circuit 350 may output and/or continuously output data chunks regardless of whether the plurality of read address ranges are continuous or discontinuous. The plurality of read address ranges will be described below with reference to FIG. 4.

In at least one example embodiment, the page read command PRDCMD, the start row address StrRA, and/or the start column address StrCA may be defined in a toggle double data rate (DDR) standard associated with a flash memory interface for high-performance applications, but the example embodiments are not limited thereto. Unlike the page read command PRDCMD, the start row address StrRA, and/or the start column address StrCA, the data read command DRDCMD may not be defined in the toggle DDR standard and may be defined individually and/or specially defined in one or more example embodiments of the inventive concepts. For example, the page read command PRDCMD may include “00h” and “30h”, but is not limited thereto. For example, the data read command DRDCMD may not include “05h” and “E0h”, but is not limited thereto.

In at least one example embodiment, although the page read command PRDCMD is defined in the toggle DDR standard, the number and/or timing of issuing the page read command PRDCMD in some example embodiments of the inventive concepts may be variously modified differently from those which are defined in the toggle DDR standard, but the example embodiments are not limited thereto.

According to one or more example embodiments of the inventive concepts, with the above configuration, the nonvolatile memory device may continuously output a plurality of target data targeted for a data read operation in units of data chunks based on the data chunk indicator, and the size of the target data may be some or all of the size of a page of data. Thus, additional signals (e.g., additional commands and/or additional addresses) need not be generated, intervened, and/or applied, etc., between one data chunk and another data chunk output from the nonvolatile memory device, etc. The nonvolatile memory device may reduce, remove, and/or prevent the generation and/or intervention of additional signals, and thus the input/output performance of the nonvolatile memory device and/or a memory system may be improved, may be more efficient, etc.

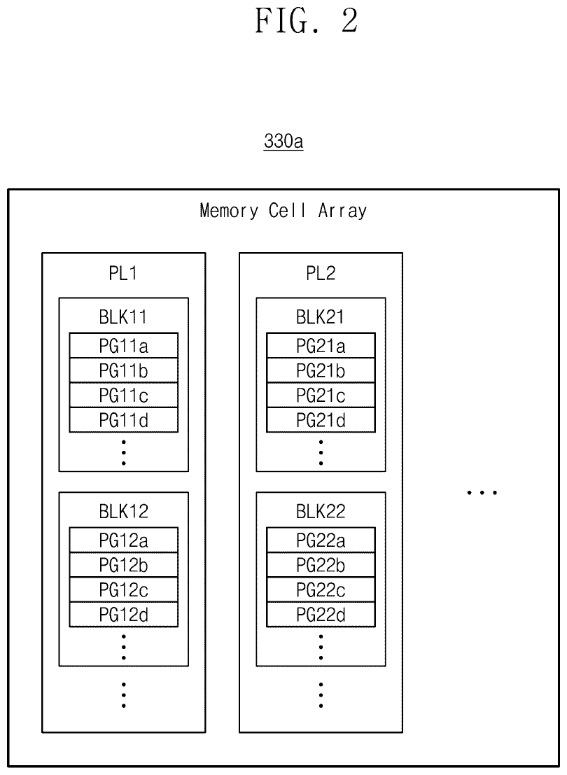

FIG. 2 is a diagram explaining planes, blocks, and pages included in a memory cell array of FIG. 1 according to at least one example embodiment.

Referring to FIG. 1 and FIG. 2, a memory cell array 330a may correspond to the memory cell array 330, but the example embodiments are not limited thereto.

The memory cell array 330a may include a plurality of planes, e.g., PL1 and PL2, etc. The plane PL1 may include a plurality of blocks, e.g., BLK11 and BLK12, etc., and the plane PL2 may include a plurality of blocks, e.g., BLK21 and BLK22, etc., but are not limited thereto. The block BLK11 may include a plurality of pages, e.g., PG11a, PG11b, PG11c, and PG11d, etc., and the block BLK12 may include a plurality of pages, e.g., PG12a, PG12b, PG12c, and PG12d, etc., but are not limited thereto. The block BLK21 may include a plurality of pages, e.g., PG21a, PG21b, PG21c, and PG21d, etc., and the block BLK22 may include a plurality of pages, e.g., PG22a, PG22b, PG22c, and PG22d, etc.

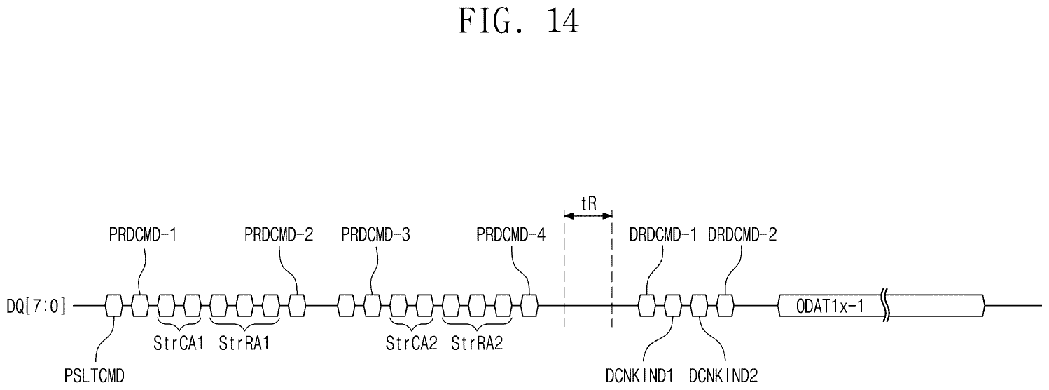

In at least one example embodiment, one of the plurality of pages PG11a to PG11d, PG12a to PG12d, PG21a to PG21d, and PG22a to PG22d may include target memory cells of the memory cell array 330a for and/or associated with a read operation of the nonvolatile memory device 300, and may store and/or contain the first page data PGDAT1. Accordingly, the memory cell array 330a may output the first page data PGDAT1 based on the start row address StrRA, and the page buffer circuit 350 may output one or more (e.g., some or all) of the plurality of first data chunks DCNK11, DCNK12, DCNK13, and the like, based on the data chunk indicator DCNKIND. However, the example embodiments of the inventive concepts are not limited thereto. In another example embodiment, data chunks may be defined with respect to one block or one plane rather than one page (or greater than one page). When data chunks are defined for one block, the data chunks may be referred to as “a plurality of first block data chunks”, and when data chunks are defined for one plane, the data chunks may be referred to as “a plurality of first plane data chunks”, etc. The plurality of first block data chunks or the plurality of first plane data chunks may be respectively processed in the same as or similar manner to the plurality of first data chunks DCNK11, DCNK12, DCNK13, and the like. Accordingly, the page buffer circuit 350 may continuously output one or more of the plurality of first block data chunks or one or more of the plurality of plane data chunks, etc. Processing of the plurality of first block data chunks or the plurality of first plane data chunks according to some example embodiments of the inventive concepts will be described in greater detail later with reference to FIG. 14.

In FIG. 2, the memory cell array 330a includes two planes PL1 and PL2, and each plane (e.g., PL1) includes two blocks (e.g., BLK11 and BLK12), and each block (e.g., BLK11) includes four pages (e.g., PG11a, PG11b, PG11c, and PG11d), but the number of planes, blocks, and pages included in the memory cell array 330a are illustrated as examples and are not limited thereto.

FIG. 3 is a diagram explaining a start read address and a data chunk indicator of FIG. 1 according to at least one example embodiment.

Referring to FIG. 1 and FIG. 3, the memory cell array 330 may output first page data PGDAT1x based on the start read address StrRDADR.

In at least one example embodiment, the start read address StrRDADR may include the start row address StrRA and the start column address StrCA, and the start row address StrRA and the start column address StrCA may indicate the first page data PGDAT1x stored in a page PGx. The first page data PGDAT1x may include a plurality of first data chunks DCNK11x, DCNK12x, DCNK13x, DCNK14x, DCNK15x, DCNK16x, DCNK17x, and DCNK18x, but is not limited thereto. For example, the start read address StrRDADR may indicate the start of the page PGx and/or start of the data chunk DCNK11x (e.g., 401), but the example embodiments of the inventive concepts are not limited thereto.

Based on the data chunk indicator DCNKIND, the page buffer circuit 350 may output a plurality of data chunks, e.g., DCNK12x, DCNK14x, and DCNK16x, etc., among the plurality of first data chunks DCNK11x to DCNK18x.

In at least one example embodiment, the data chunk indicator DCNKIND may indicate the plurality of data chunks DCNK12x, DCNK14x, and DCNK16x, etc., from all of the plurality of first data chunks DCNK11x to DCNK18x (e.g., 403), and the page buffer circuit 350 may generate and/or transmit output data ODAT1x including the data chunks DCNK12x, DCNK14x, and DCNK16x, etc. As described above with reference to FIG. 1, the data chunks DCNK12x, DCNK14x, and DCNK16x may be continuously output, but is not limited thereto.

FIG. 4 is a diagram explaining one or more of a plurality of first data chunks output from the page buffer circuit of FIG. 1 based on a data chunk indicator according to at least one example embodiment.

In FIG. 4, a plurality of read address ranges RDADRRNGs and pages PG(x−1), PGx, PG(x+1) (where x is an integer of 2 or more) are illustrated. The plurality of read address ranges RDADRRNGs may indicate address ranges (e.g., ADRRRNG1, ADRRRNG2, and ADRRRNG3, etc.) for reading target data from target memory cells of a memory cell array, which are targets for reading data. The pages PG(x−1), PGx, PG(x+1) may be adjacent to each other in the memory cell array, and the page PGx may include the target memory cells for and/or to be used in storing the target data. For example, the plurality of read address ranges RDADRRNGs may include two or more discontinuous address ranges of the memory cell array, but is not limited thereto.

Referring to FIG. 4, an address range ADRRNG1 may correspond to a data chunk DCNK12x, an address range ADRRNG2 may correspond to a data chunk DCNK14x, and an address range ADRRNG3 may correspond to a data chunk DCNK16x, but the example embodiments are not limited thereto.

In FIG. 4, there may be a gap between the address ranges ADRRRNG1 and ADRRRNG2 and/or between the address ranges ADRRRNG2 and ADRRRNG3, which may indicate that the address ranges ADRRRNG1 to ADRRNG3 are discontinuous in an address space of the memory cell array. In this case, the data chunks DCNK12x, DCNK14x, and DCNK16x may also be discontinuously stored in the first page data PGDAT1x (and/or may be discontinuously stored in latches of the page buffer circuit).

As described above with reference to FIG. 1 and FIG. 3, the relationship between the plurality of read address ranges RDADRRNGs and the data chunks DCNK12x, DCNK14x, and DCNK16x may be identified by the data chunk indicator DCNKIND regardless of whether the address ranges are continuous or discontinuous.

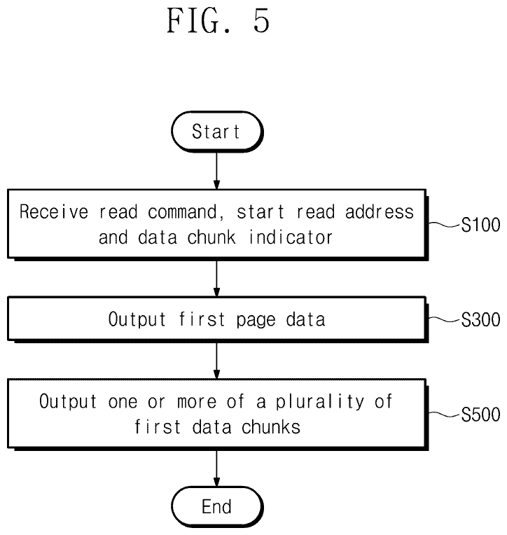

FIG. 5 is a flowchart illustrating an operating method of a nonvolatile memory device according to at least one example embodiment of the inventive concepts.

Referring to FIG. 1 and FIG. 5, the control circuit 310 may receive the read command RDCMD, the start read address StrRDADR, and/or the data chunk indicator DCNKIND (S100), but is not limited thereto. The read command RDCMD may include the page read command PRDCMD and the data read command DRDCMD, and the start read address StrRDADR may include the start row address StrRA and the start column address StrCA, but are not limited thereto.

The memory cell array 330 may output the first page data PGDAT1 including the plurality of first data chunks, e.g., DCNK11, DCNK12, DCNK13, and the like, based on the start row address StrRA (S300).

The page buffer circuit 350 may output one or more (e.g., DCNKa, . . . ) of the plurality of first data chunks, e.g., DCNK11, DCNK12, DCNK13, and the like, based on the data chunk indicator DCNKIND (S500).

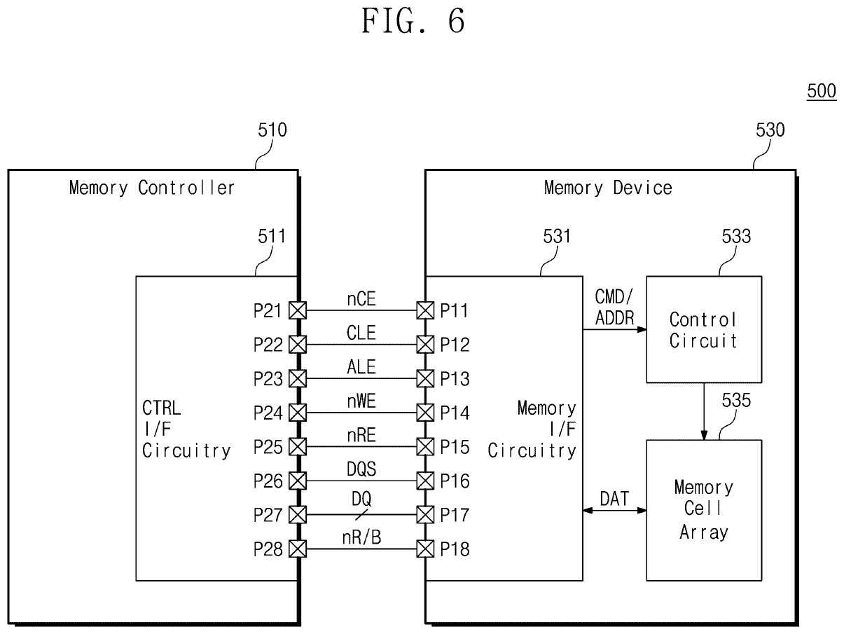

FIG. 6 is a block diagram explaining data and other control signals between the nonvolatile memory device of FIG. 1 and the memory controller communicating therewith according to at least one example embodiment.

Referring to FIG. 6, a memory system 500 may correspond to the memory system 10 of FIG. 1, but is not limited thereto, and may include at least one memory controller 510 and at least one nonvolatile memory device 530, etc., but the example embodiments are not limited thereto.

The nonvolatile memory device 530 may correspond to one of a plurality of nonvolatile memory devices communicating with the memory controller 510 based on one or more of a plurality of channels. The memory controller 510 may correspond to the memory controller 100 of FIG. 1, and the memory device 530 may correspond to the nonvolatile memory device 300 of FIG. 1, but the example embodiments are not limited thereto.

The memory device 530 may include a plurality of pins, e.g., first to eighth pins P11 to P18, a memory interface circuit 531, a control circuit 533, and/or a memory cell array 535, etc., but the example embodiments are not limited thereto. According to some example embodiments, one or more of the memory controller 510, the memory interface circuit 531, and/or the control circuit 533, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The memory interface circuit 531 may receive at least one chip enable signal nCE from the memory controller 510 through, e.g., the first pin P11. The memory interface circuit 531 may transmit and/or receive signals to and/or from the memory controller 510 through, e.g., the second to eighth pins P12 to P18, according to and/or based on the chip enable signal nCE, but is not limited thereto. For example, when the chip enable signal nCE is in an enable state (e.g., a low level, etc.), the memory interface circuit 531 may transmit and/or receive the signals to and/or from the memory controller 510 through, e.g., the second to eighth pins P12 to P18, but is not limited thereto.

The memory interface circuit 531 may receive a command latch enable signal CLE, an address latch enable signal ALE, and/or a write enable signal nWE from the memory controller 510 through, e.g., the second to fourth pins P12 to P14, but is not limited thereto. The memory interface circuit 531 may receive a data signal DQ from the memory controller 510 through, e.g., the seventh pin P17, and/or may transmit the data signal DQ to the memory controller 510 through, e.g., the seventh pin P17, etc. A command CMD, an address ADDR, and/or data DAT may be transferred through the data signal DQ, but is not limited thereto. For example, the data signal DQ may be transferred through a plurality of data signal lines. In this case, the seventh pin P17 may include a plurality of pins corresponding to a plurality of data signals, but the example embodiments are not limited thereto. For example, the data signal DQ may include the read command RDCMD, the start read address StrRDADR, and/or the data chunk indicator DCNKIND, which were described above with reference to FIG. 1 and FIG. 3, but are not limited thereto. For example, the command CMD may include the read command RDCMD, and the address ADDR may include the start read address StrRDADR and/or the data chunk indicator DCNKIND, etc.

The memory interface circuit 531 may obtain the command CMD from the data signal DQ received during an enable period (e.g., a high level state, etc.) of the command latch enable signal CLE based on toggle timings of the write enable signal nWE. The memory interface circuit 531 may obtain the address ADDR from the data signal DQ received during an enable period (e.g., a high level state, etc.) of the address latch enable signal ALE based on the toggle timings of the write enable signal nWE.

In at least one example embodiment, the write enable signal nWE may maintain a static state (e.g., a high level or a low level, etc.) and then may toggle between the high level and the low level. For example, the write enable signal nWE may toggle during a period in which the command CMD and/or the address ADDR is transmitted. Accordingly, the memory interface circuit 531 may acquire the command CMD and/or the address ADDR based on the toggle timings of the write enable signal nWE, etc.

The memory interface circuit 531 may receive a read enable signal nRE from the memory controller 510 through, e.g., the fifth pin P15. The memory interface circuit 531 may receive a data strobe signal DQS from the memory controller 510 through, e.g., the sixth pin P16, and/or may transmit the data strobe signal DQS to the memory controller 510 through, e.g., the sixth pin P16.

In an operation of outputting the data DAT of the nonvolatile memory device 530, the memory interface circuit 531 may receive the read enable signal nRE which toggles through, e.g., the fifth pin P15, before the memory interface circuit 531 outputs the data DAT. The memory interface circuit 531 may generate the data strobe signal DQS which toggles based on toggling of the read enable signal nRE. For example, the memory interface circuit 531 may generate the data strobe signal DQS which starts toggling after a desired and/or predetermined delay (e.g., tDQSRE) based on a toggling start time point of the read enable signal nRE. The memory interface circuit 531 may transmit the data signal DQ including the data DAT, based on the toggle timing of the data strobe signal DQS. Accordingly, the data DAT may be aligned with the toggle timing of the data strobe signal DQS and transmitted to the memory controller 510, etc.

In the data DAT input operation of the nonvolatile memory device 530, when the data signal DQ including the data DAT is received from the memory controller 510, the memory interface circuit 531 may receive the data strobe signal DQS toggling with the data DAT from the memory controller 510. The memory interface circuit 531 may acquire the data DAT from the data signal DQ based on the toggle timing of the data strobe signal DQS. For example, the memory interface circuit 531 may acquire the data DAT by sampling the data signal DQ at a rising edge and/or a falling edge of the data strobe signal DQS, but the example embodiments are not limited thereto.

The memory interface circuit 531 may transmit a ready/busy output signal nR/B to the memory controller 510 through, e.g., the eighth pin P18, but is not limited thereto. The memory interface circuit 531 may transmit state information of the nonvolatile memory device 530 to the memory controller 510 through the ready/busy output signal nR/B. When the nonvolatile memory device 530 is in a busy state (e.g., when internal operations of the nonvolatile memory device 530 are being performed), the memory interface circuit 531 may transmit the ready/busy output signal nR/B indicating the busy state to the memory controller 510. When the nonvolatile memory device 530 is in a ready state (e.g., when internal operations of the nonvolatile memory device 530 are not performed or are completed), the memory interface circuit 531 may transmit the ready/busy output signal nR/B indicating the ready state to the memory controller 510. For example, while the nonvolatile memory device 530 reads the data DAT from the memory cell array 535 in response to the page read command, the memory interface circuit 531 may transmit the ready/busy output signal nR/B indicating the busy state (e.g., a low level, etc.) to the memory controller 510. For example, while the nonvolatile memory device 530 programs the data DAT to the memory cell array 535 in response to a program command, the memory interface circuit 531 may transmit the ready/busy output signal nR/B indicating the busy state to the memory controller 510, but is not limited thereto.

The control circuit 533 may control various operations of the nonvolatile memory device 530. The control circuit 533 may receive the command/address CMD/ADDR obtained from the memory interface circuit 531. The control circuit 533 may generate the control signals for controlling other components of the nonvolatile memory device 530 according to and/or based on the received command/address CMD/ADDR. For example, the control circuit 533 may generate various control signals for programming the data DAT in the memory cell array 535 and/or for reading the data DAT from the memory cell array 535, etc.

The memory cell array 535 may store the data DAT obtained from the memory interface circuit 531 under the control of the control circuit 533. The memory cell array 535 may output the stored data DAT to the memory interface circuit 531 under the control of the control circuit 533.

The memory cell array 535 may include a plurality of memory cells. For example, the plurality of memory cells may be flash memory cells. However, the example embodiments of the inventive concepts are not limited thereto, and the memory cells may be, for example, resistive random access memory (RRAM) cells, ferroelectric random access memory (FRAM) cells, phase change random access memory (PRAM) cells, thyristor random access memory (TRAM) cells, and/or magnetic random access memory (MRAM) cells, etc.

The memory controller 510 may include a plurality of pins, e.g., first to eighth pins P21 to P28, etc., and/or a controller interface circuit (CTRL I/F Circuitry) 511, etc. The first to eighth pins P21 to P28 may correspond to the first to eighth pins P11 to P18 of the nonvolatile memory device 530, but the example embodiments are not limited thereto.

The controller interface circuit 511 may transmit the chip enable signal nCE to the nonvolatile memory device 530 through the first pin P21, but is not limited thereto. The controller interface circuit 511 may transmit and/or receive the signals to and/or from the nonvolatile memory device 530 selected through the chip enable signal nCE through, e.g., the second to eighth pins P22 to P28.

The controller interface circuit 511 may transmit the command latch enable signal CLE, the address latch enable signal ALE, and/or the write enable signal nWE to the nonvolatile memory device 530 through, e.g., the second to fourth pins P22 to P24. The controller interface circuit 511 may transmit the data signal DQ to the nonvolatile memory device 530 through, e.g., the seventh pin P27, and/or may receive the data signal DQ from the nonvolatile memory device 530 through, e.g., the seventh pin P27.

The controller interface circuit 511 may transmit the data signal DQ including the command CMD and/or the address ADDR to the nonvolatile memory device 530 together with the write enable signal nWE which toggles (e.g., toggles between states, etc.). The controller interface circuit 511 may transmit the data signal DQ including the command CMD to the nonvolatile memory device 530 as the controller interface circuit 511 transmits the command latch enable signal CLE having the enable state and may transmit the data signal DQ including the address ADDR to the nonvolatile memory device 530 as the controller interface circuit 511 transmits the address latch enable signal ALE having the enable state.

The controller interface circuit 511 may transmit the read enable signal nRE to the nonvolatile memory device 530 through, e.g., the fifth pin P25. The controller interface circuit 511 may receive the data strobe signal DQS from the nonvolatile memory device 530 through, e.g., the sixth pin P26, and/or may transmit the data strobe signal DQS to the nonvolatile memory device 530 through, e.g., the sixth pin P26.

In the data DAT output operation of the nonvolatile memory device 530, the controller interface circuit 511 may generate the read enable signal nRE which toggles (e.g., transitions between 0 to 1 or ON and OFF, etc.) and may transmit the read enable signal nRE to the nonvolatile memory device 530. For example, the controller interface circuit 511 may generate the read enable signal nRE which changes from a fixed state (e.g., a high level or a low level) to a toggle state (e.g., an opposite state, etc.) before the data DAT is output. Accordingly, the data strobe signal DQS which toggles based on the read enable signal nRE may be generated in the nonvolatile memory device 530. The controller interface circuit 511 may receive from the nonvolatile memory device 530, the data signal DQ including the data DAT together with the data strobe signal DQS which toggles between states. The controller interface circuit 511 may obtain the data DAT from the data signal DQ based on the toggle timing of the data strobe signal DQS.

In the data DAT input operation of the nonvolatile memory device 530, the controller interface circuit 511 may generate the data strobe signal DQS which toggles (e.g., transitions between 0 to 1 or ON and OFF, etc.). For example, the controller interface circuit 511 may generate the data strobe signal DQS which changes from a fixed state (e.g., a high level or a low level) to a toggle state before the controller interface circuit 511 transmits the data DAT, etc. The controller interface circuit 511 may transmit the data signal DQ including the data DAT to the nonvolatile memory device 530 based on the toggle timings of the data strobe signal DQS.

The controller interface circuit 511 may receive the ready/busy output signal nR/B from the nonvolatile memory device 530 through the eighth pin P28, but is not limited thereto. The controller interface circuit 511 may determine the state information of the nonvolatile memory device 530 based on the ready/busy output signal nR/B.

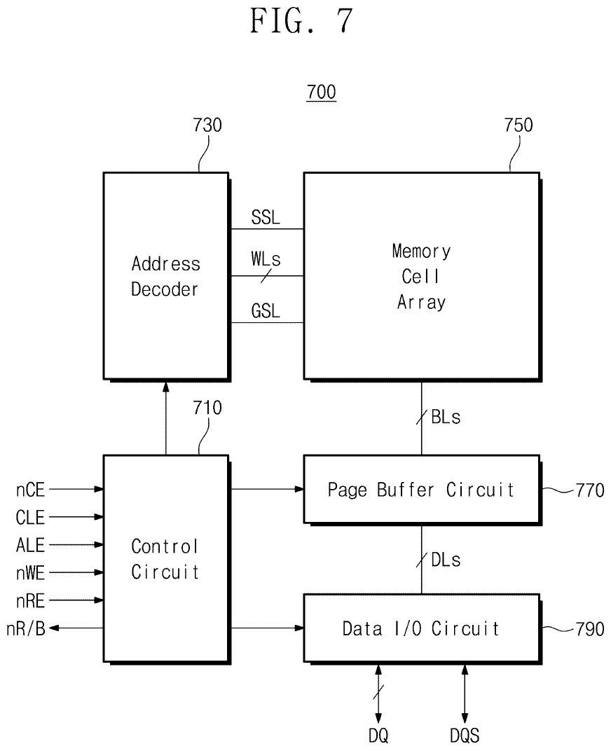

FIG. 7 is a block diagram illustrating at least one example embodiment of a nonvolatile memory device of FIG. 1.

Referring to FIG. 7, a nonvolatile memory device 700 may include a control circuit 710, an address decoder 730, a memory cell array 750, a page buffer circuit 770, and/or a data input/output circuit 790, etc., but is not limited thereto. According to some example embodiments, one or more of the control circuit 710, the address decoder 730, the page buffer circuit 770, and/or the data input/output circuit 790, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The memory cell array 750 may be coupled to the address decoder 730 through at least one string selection line SSL, a plurality of word lines WLs, and/or at least one ground selection line GSL, etc. Also, the memory cell array 750 may be coupled to the page buffer circuit 770 through a plurality of bit lines BLs. The page buffer circuit 770 may be coupled to the data input/output circuit 790 through a plurality of data lines DLs.

The memory cell array 750 may include the plurality of memory cells connected to the plurality of word lines WLs and the plurality of bit lines BLs.

According to at least one example embodiment, the memory cell array 750 may be a three-dimensional memory cell array formed on a substrate in a three-dimensional structure (e.g., a vertical structure), but is not limited thereto. In this case, the memory cell array 750 may include vertical memory cell strings including a plurality of memory cells formed by being stacked on each other. A detailed description of the three-dimensional memory cell array is described in U.S. Registration Pat. Nos. 7,679,133; 8,553,466; 8,654,587; 8,559,235 and U.S. Publication No. 2011/0233648, incorporated by reference herein.

In another example embodiment, the memory cell array 750 may be a two-dimensional memory cell array formed on a substrate in a two-dimensional structure (e.g., a horizontal structure, etc.), but is not limited thereto.

The control circuit 710 may receive the chip enable signal nCE, the command latch enable signal CLE, the address latch enable signal ALE, the write enable signal nWE, and/or the read enable signal nRE described above with reference to FIG. 6, and may output a ready/busy output signal nRB, but the example embodiments are not limited thereto.

The data input/output circuit 790 may transmit and/or receive the data signal DQ and/or the data strobe signal DQS to and/or from the memory controller. The control circuit 710 may transmit and/or receive the data signal DQ and/or the data strobe signal DQS through the data input/output circuit 790.

The memory cell array 750 may output the first page data PGDAT1 of FIG. 1 to the page buffer circuit 770 through the plurality of bit lines BLs in a read operation of target data, and the page buffer circuit 770 may output some or all of the first page data PGDAT1 to the data input/output circuit 790 through the plurality of data lines DLs.

FIG. 8 is a timing diagram explaining at least one example embodiment of an operation of the nonvolatile memory device of FIG. 1, 6 or 7, but the example embodiments are not limited thereto.

In FIG. 8, the write enable signal nWE, the read enable signal nRE, the data strobe signal DQS, and the data signal DQ are illustrated over a time period between t1 to t5. RE may be an inverted signal of the read enable signal nRE, and nDQS may be an inverted signal of the data strobe signal DQS. The signals nWE, nRE, DQS, and DQ may have states or levels as described above with reference to FIG. 6, and the read command RDCMD, the start read address StrRDADR, and the data chunk indicator DCNKIND described above with reference to FIG. 1 and FIG. 3 may be transmitted through the data signal DQ, but the example embodiments are not limited thereto.

Referring to FIG. 1, FIG. 7, and FIG. 8, the write enable signal nWE may toggle between t1 and t2, the read enable signal nRE may be maintained at the high level, and the data strobe signal DQS may have a high impedance state (e.g., “Hi-Z”). In this case, the page read command PRDCMD and the start read address StrRDADR may be received through the data signal DQ based on the toggle timings of the write enable signal nWE.

For example, the page read command PRDCMD may include a plurality of read commands, e.g., first read command PRDCMDa and a second read command PRDCMDb, but is not limited thereto. The start read address StrRDADR may include the start row address StrRA and the start column address StrCA. For example, between t1 and t2, the control circuit may sequentially receive the first read command PRDCMDa, the start read address StrRDADR, and the second read command PRDCMDb, but is not limited thereto. For example, when the memory cells in the memory cell array include multi-level cells, before the first read command PRDCMDa is received, a page selection command PSLTCMD indicating one of least significant bit (LSB) page, a central significant bit (CSB) page, and a most significant bit (MSB) page may be further received, etc.

Between t2 and t3, the write enable signal nWE may maintain the high level, the read enable signal nRE may maintain the low level, and the data strobe signal DQS may maintain the high impedance state, but are not limited thereto. For example, between t2 and t3, during a time interval tR, the memory cell array may output page data (e.g., PGDAT1 of FIG. 1) to the page buffer circuit, etc.

Between t3 and t4, the write enable signal nWE may toggle again and may have the high level, the read enable signal nRE may first maintain the high level and then toggle, and the data strobe signal DQS may maintain the high impedance state. In this case, data read commands DRDCMDa and DRDCMDb and the data chunk indicator DCNKIND may be received through the data signal DQ based on the toggle timings of the write enable signal nWE, but the example embodiments are not limited.

For example, the data read command DRDCMD may include the third read command DRDCMDa and the fourth read command DRDCMDb, but is not limited thereto. The data chunk indicator DCNKIND may individually indicate whether the sizes of each of the data chunks are partial (e.g., has a size less than a whole page of data) or entire of the page data (e.g., are equal to the size of a whole page of data) output to the page buffer circuit between t2 and t3. For example, between t3 and t4, the control circuit may sequentially receive the third read command DRDCMDa, the data chunk indicator DCNKIND, and the fourth read command DRDCMDb, but is not limited thereto.

For example, the read enable signal nRE may toggle after a desired and/or predetermined delay (e.g., tWHR2) from the time when the write enable signal nWE has the high level after toggling.

Between t4 and t5, the write enable signal nWE may maintain the high level, and the read enable signal nRE and the data strobe signal DQS may toggle, but is not limited thereto. In this case, the output data ODAT1x may be output through the data signal DQ based on the toggle timings of the data strobe signal DQS.

For example, the output data ODAT1x may be output after a desired and/or predetermined delay (e.g., tDQSRE) based on a toggling start time (e.g., between t3 and t4, etc.) of the read enable signal nRE. For example, as described above with reference to FIG. 1, the output data ODAT1x may include one or more of the plurality of first data chunks, and the page buffer circuit may output and/or continuously output two or more of the plurality of first data chunks after a desired and/or predetermined time (e.g., tWHR2+tDQSRE) elapses from a time point at which the nonvolatile memory device receives the fourth read command DRDCMDb, but the example embodiments are not limited thereto.

In at least one example embodiment, the control circuit may sequentially receive the first read command PRDCMDa, the start read address StrRDADR, the second read command PRDCMDb, the third read command DRDCMDa, the data chunk indicator DCNKIND, and the fourth read command DRDCMDb between t1 and t4, but the example embodiments are not limited thereto.

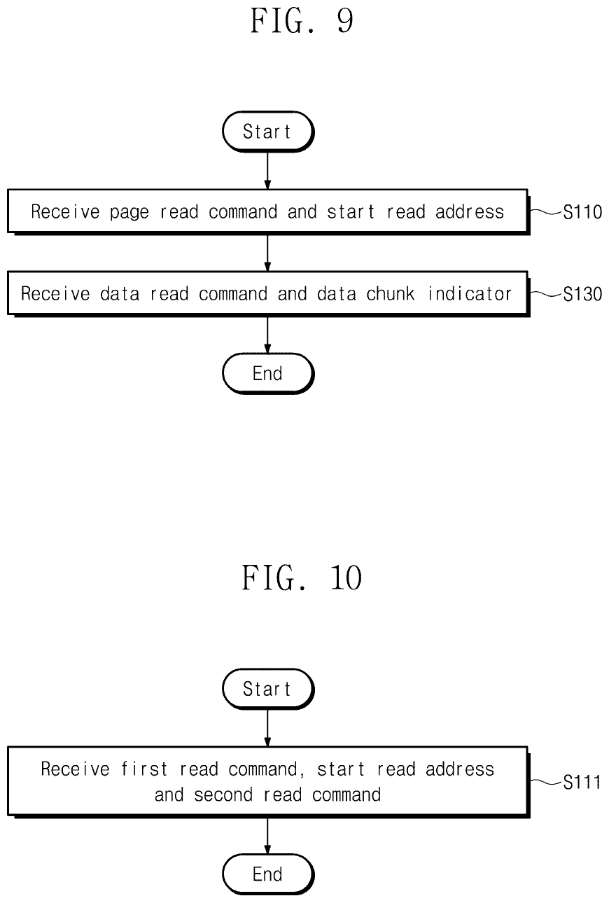

FIG. 9 is a flowchart explaining an operation in which a control circuit of FIG. 7 receives a read command, a start read address, and a data chunk indicator according to at least one example embodiment.

Referring to FIGS. 1, 5, 7, 8, and 9, the control circuit (e.g., 310 of FIG. 1, 533 of FIG. 6, 710 of FIG. 7, etc.) may receive the page read command PRDCMD and the start read address StrRDADR (S110), but the example embodiments are not limited thereto.

In at least one example embodiment, the page read command PRDCMD may be a command for outputting page data stored in one page of the memory cell array (e.g., 330 of FIG. 1, 535 of FIG. 6, 750 of FIG. 7, etc.) from the memory cell array to the page buffer circuit (e.g., 350 of FIG. 1, 770 of FIG. 7, etc.).

The control circuit may receive the data read command DRDCMD and the data chunk indicator DCNKIND, etc., (S130).

In at least one example embodiment, the data read command DRDCMD may be a command for outputting some or all of the page data from the page buffer circuit to the data input/output circuit (e.g., 790 of FIG. 7, etc.).

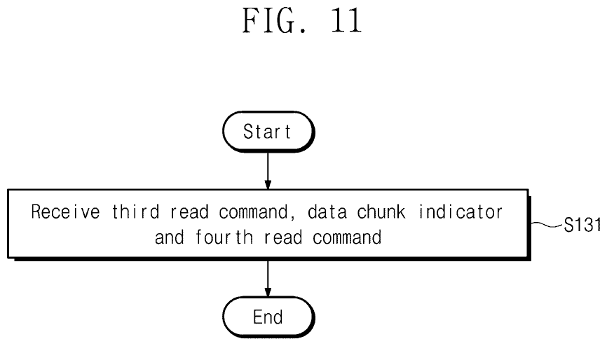

FIG. 10 is a flowchart illustrating at least one example embodiment of an operation in which a control circuit of FIG. 7 receives a read command and a start read address.

Referring to FIG. 1, FIG. 5, FIG. 7, FIG. 8, and FIG. 9, the control circuit (e.g., 310 of FIG. 1, 533 of FIG. 6, 710 of FIG. 7, etc.) may sequentially receive the first read command PRDCMDa, the start read address StrRDADR, and the second read command PRDCMDb (S111), but the example embodiments are not limited thereto.

In at least one example embodiment, the page read command PRDCMD may include the first read command PRDCMDa and the second read command PRDCMDb, etc.

According to at least one example embodiment, S110 of FIG. 9 may include S111 of FIG. 10, but the example embodiments are not limited thereto.

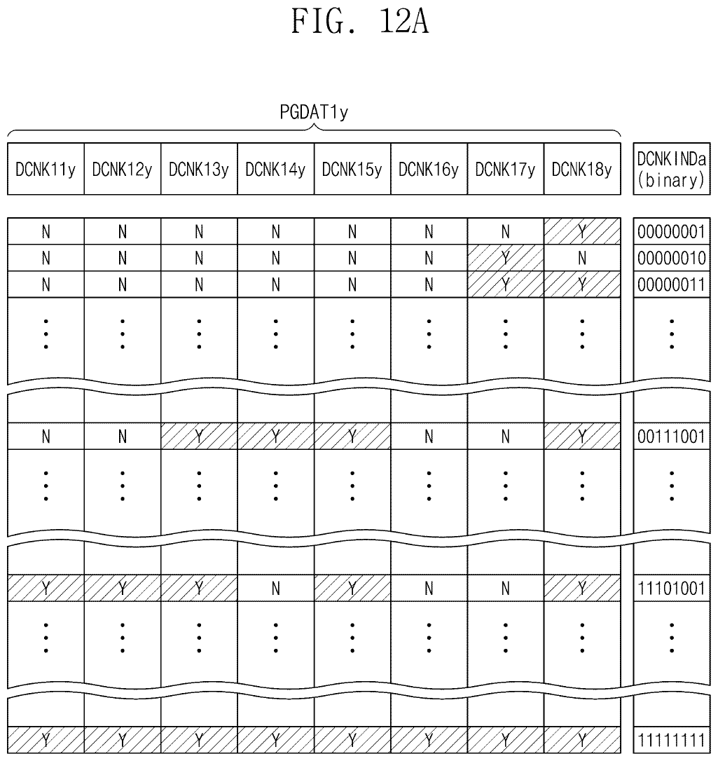

FIG. 11 is a flowchart illustrating at least one example embodiment of an operation in which a control circuit of FIG. 7 receives a read command and a data chunk indicator.

Referring to FIG. 1, FIG. 5, FIG. 7, FIG. 8, and FIG. 9, the control circuit (e.g., 310 of FIG. 1, 533 of FIG. 6, 710 of FIG. 7, etc.) may sequentially receive the third read command DRDCMda, the data chunk indicator DCNKIND, and the fourth read command DRDCMDb, etc., (S131), but is not limited thereto.

In at least one example embodiment, the data read command DRDCMD may include the third read command DRDCMDa and the fourth read command DRDCMDb, but the example embodiments are not limited thereto.

In at least one example embodiment, S130 of FIG. 9 may include S131 of FIG. 11, but the example embodiments are not limited thereto.

FIG. 12A and FIG. 12B are diagrams illustrating at least one example embodiment of a data chunk indicator of FIG. 1.

In FIG. 12A and FIG. 12B, first page data PGDAT1y and data chunk indicators DCNKINDa and DCNKINDb are illustrated, but the example embodiments are not limited thereto. The first page data PGDAT1y may correspond to the page data (e.g., PGDAT1 of FIG. 1, PGDAT1x of FIG. 3, etc.) output from the memory cell array to the page buffer circuit.

As described above with reference to FIG. 1, the data chunk indicator DCNKIND may individually indicate a plurality of first data chunks, e.g., DCNK11y, DCNK12y, DCNK13y, DCNK14y, DCNK15y, DCNK16y, DCNK17y, and DCNK18y, etc., included in the first page data PGDAT1y output from the memory cell array (e.g., 330 of FIG. 1, etc.). Data chunks indicated by the data chunk indicator DCNKIND may be output from the page buffer circuit (e.g., 350 of FIG. 1, etc.) to the data input/output circuit.

Referring to FIG. 1 and FIG. 12A, the data chunk indicator DCNKINDa may include binary data indicating one or more of the plurality of first data chunks DCNK11y to DCNK18y, but is not limited thereto.

In at least one example embodiment, the data chunk indicator DCNKINDa may indicate each of the plurality of first data chunks DCNK11y to DCNK18y using a bitmap type, but is not limited thereto.

For example, the number of plurality of first data chunks DCNK11y to DCNK18y may be N (N being an integer of 2 or more), and in this case, the data chunk indicator DCNKINDa may be N-bit data.

For example, when the data chunk indicator DCNKINDa indicates the data chunk DCNK18y, the data chunk indicator DCNKINDa may have a value of “00000001”. When the data chunk indicator DCNKINDa indicates the data chunk DCNK17y, the data chunk indicator DCNKINDa may have a value of “00000010”. When the data chunk indicator DCNKINDa indicates the data chunks DCNK17y and DCNK18y, the data chunk indicator DCNKINDa may have a value of “00000011”. When the data chunk indicator DCNKINDa indicates the data chunks DCNK13y, DCNK14y, DCNK15y, and DCNK18y, the data chunk indicator DCNKINDa may have a value of “00111001”. When the data chunk indicator DCNKINDa indicates the data chunks DCNK11y to DCNK13y, DCNK15y, and DCNK18y, the data chunk indicator DCNKINDa may have a value of “11101001”. When the data chunk indicator DCNKINDa indicates the data chunks DCNK11y to DCNK18y, the data chunk indicator DCNKINDa may have a value of “11111111”. However, the example embodiments are not limited thereto, and the data chunk indicators may have other values.

Referring to FIG. 1 and FIG. 12B, the data chunk indicator DCNKINDb may include decimal data indicating one or more of the plurality of data chunks DCNK11y to DCNK18y, etc.

In at least one example embodiment, the data chunk indicator DCNKINDb may indicate each of the plurality of data chunks DCNK11y to DCNK18y by using an offset type. For example, a data chunk having a smallest column address from among the plurality of data chunks DCNK11y to DCNK18y may be a reference, but the example embodiments are not limited thereto. The remaining data chunks excluding the data chunk as a reference may be expressed based on a distance from the reference data chunk.

For example, the number of the plurality of first data chunks DCNK11y to DCNK18y may be N, and in this case, the data chunk indicator DCNKINDb may be data having a digit less than or equal to N.

For example, when the data chunk indicator DCNKINDb indicates the data chunk DCNK18y, the data chunk indicator DCNKINDb may have a value of “8”. When the data chunk indicator DCNKINDb indicates the data chunk DCNK17y, the data chunk indicator DCNKINDb may have a value of “7”. When the data chunk indicator DCNKINDb indicates the data chunks DCNK17y and DCNK18y, the data chunk indicator DCNKINDb may have values of “7” and “8”. When the data chunk indicator DCNKINDb indicates the data chunks DCNK13y, DCNK14y, DCNK15y, and DCNK18y, the data chunk indicator DCNKINDb may have values of “3”, “4”, “5”, and “8”. When the data chunk indicator DCNKINDb indicates the data chunks DCNK11y to DCNK13y, DCNK15y, and DCNK18y, the data chunk indicator DCNKINDb may have values of “1”, “2”, “3”, “5”, and “8”. When the data chunk indicator DCNKINDb indicates the data chunks DCNK11y to DCNK18y, the data chunk indicator DCNKINDb may have values of “1”, “2”, “3”, “4”, “5”, “6”, “7”, and “8”.

With reference to FIG. 12A and FIG. 12B, some example embodiments in which the data chunk indicator DCNKIND includes binary data or decimal data are described, but the scope of the example embodiments of the inventive concepts are not limited thereto. In another example embodiment, the data chunk indicator DCNKIND may have various data formats which may respectively indicate one or more of the plurality of data chunks DCNK11y to DCNK18y.

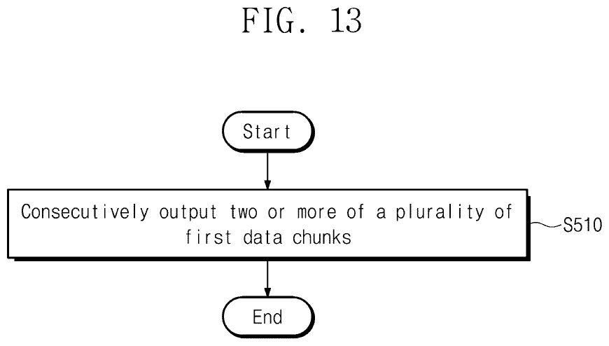

FIG. 13 is a flowchart illustrating at least one example embodiment of an operation in which a control circuit of FIG. 7 outputs one or more of a plurality of first data chunks.

Referring to FIG. 1, FIG. 5, FIG. 7, FIG. 8, and FIG. 13, the page buffer circuit (e.g., 350 in FIG. 1, 770 in FIG. 7, etc.) may output and/or continuously output two or more data chunk indicators (e.g., DCNKa, . . . ) indicated by the data chunk indicator DCNKIND from among the plurality of first data chunks DCNK11, DCNK12, DCNK13, and the like (S510).

In at least one example embodiment, S500 of FIG. 5 may include S510 of FIG. 13, but is not limited thereto.

FIG. 14 is a timing diagram explaining at least one example embodiment of an operation of a nonvolatile memory device of FIG. 7. As described above with reference to FIG. 2, data chunks may be defined not for one page but for data sizes smaller than one page, such as one block or one plane, etc. When the sizes of data chunks are defined as being equal to one block, the data chunks may be referred to as “a plurality of first block data chunks”, and when the sizes of data chunks are defined as being equal to one plane, the data chunks may be referred to as “a plurality of first plane data chunks”, etc. Each of the plurality of first block data chunks or the plurality of first plane data chunks may be processed in the same as, or similar manner, to the plurality of first data chunks DCNK11, DCNK12, DCNK13, and the like. Thus, the page buffer circuit (e.g., 350 in FIG. 1, etc.) may output one or more of the plurality of first block data chunks defined as being equal to the size of one block based on the data chunk indicator or one or more of the plurality of first plane data chunks defined as being equal to the size of one plane, and may output and/or continuously output two or more of the plurality of first block data chunks or two or more of the plurality of first plane data chunks, etc., but the example embodiments are not limited thereto.

In at least one example embodiment, each of the plurality of first block data chunks or the plurality of first plane data chunks may be stored in memory cells arranged in the same row of the memory cell array as the data chunks described above with reference to FIG. 8, and may be stored in memory cells arranged in two or more different rows of the memory cell array, unlike the above data chunks, but the example embodiments are not limited thereto. Thus, in a manner similar to the manner described above with reference to FIG. 3, to indicate the start of the plurality of first block data chunks or the start of the plurality of first plane data chunks, the number of read commands included in the page read command (e.g., PRDCMD in FIG. 1) may remain unchanged (e.g., two) or may increase (e.g., three or more), and the number of start row addresses and the number of start column addresses included in the start read address (e.g., StrRDADR in FIG. 1) may also remain unchanged (e.g., one, respectively) or may increase (e.g., two or more, respectively). However, the number of read commands included in the data read command (e.g., DRDCMD in FIG. 1) may remain unchanged (e.g., two) regardless of whether the plurality of first block data chunks or the plurality of first plane data chunks are stored in memory cells placed in the same row of the memory cell array or placed in two or more different rows of the memory cell array. The number of data chunk indicators for indicating one or more of the plurality of first block data chunks or one or more of the plurality of first plane data chunks may be unchanged or may be increased compared to the case indicating a plurality of data chunks.

For example, when each of the plurality of first block data chunks or each of the plurality of first plane data chunks is stored in memory cells arranged in the same row of the memory cell array, in the same manner as described above with reference to FIG. 8, the page read command may include two read commands, the start read address may include one start row address and one start column address, and the data read command may include two read commands, but the example embodiments are not limited thereto. The number of data chunk indicators may be one, but is not limited thereto.

For example, when each of the plurality of first block data chunks or each of the plurality of first plane data chunks are stored in memory cells arranged in two different rows of the memory cell array, as illustrated in FIG. 14, the page read command may include four read commands, the start read address may include two start row addresses and two start column addresses, and the data read command may include two read commands, but the example embodiments are not limited thereto. The number of data chunk indicators may be two, but is not limited thereto.

Referring to FIG. 14, when each of the plurality of first block data chunks or each of the plurality of first plane data chunks are stored in memory cells arranged in two different rows of a memory cell array, at least one example embodiment of outputting one or more of the plurality of first block data chunks or one or more of the plurality of plane data chunks is illustrated, but the example embodiments are not limited thereto.

In at least one example embodiment, the control circuit (e.g., 310 of FIG. 1, 533 of FIG. 6, and 710 of FIG. 7) may receive the page read command including, e.g., read commands PRDCMD-1, PRDCMD-2, PRDCMD-3, and PRDCMD-4, etc., and a data read command including, e.g., read commands DRDCMD-1 and DRDCMD-2, etc., but the example embodiments are not limited thereto. The control circuit may receive a first start read address including a first start row address StrRA1 and a first start column address StrCA1, and a second start read address including a second start row address StrRA2 and a second start column address StrCA2, etc. The control circuit may receive a first data chunk indicator DCNKIND1 and a second data chunk indicator DCNKIND2 indicating one or more of the plurality of first block data chunks or one or more of the plurality of plane data chunks.

For example, the control circuit may sequentially receive the read command PRDCMD-1, the first start column address StrCA1, the first start row address StrRA1, and the read command PRDCMD-2, but the example embodiments are not limited thereto. The control circuit may sequentially receive the read command PRDCMD-3, the second start column address StrCA2, the second start row address StrRA2, and the read command PRDCMD-4, etc. During the tR time period, the memory cell array (e.g., 330 in FIG. 1, etc.) may output block data including the plurality of first block data chunks or plane data including the plurality of plane data chunks to the page buffer circuit (e.g., 350 in FIG. 1, etc.) based on the first start row address StrRA1 and the second start row address StrRA2.

For example, the control circuit may sequentially receive the read command DRDCMD-1, the first data chunk indicator DCNKIND1, the second data chunk indicator DCNKIND2, and the read command DRDCMD-2, etc. The first data chunk indicator DCNKIND1 may indicate one or more of the data block chunks or the data plane chunks stored in memory cells arranged in one row, etc., and the second data chunk indicator DCNKIND2 may indicate one or more of the data block chunks or the data plane chunks stored in memory cells arranged in another row, etc.

For example, the page buffer circuit may output and/or continuously output two or more of the plurality of first block data chunks and/or two or more of the plurality of first data page chunks based on the first data chunk indicator DCNKIND1 and the second data chunk indicator DCNKIND2, but is not limited thereto.

In at least one example embodiment, when the memory cells of the memory cell array include multi-level cells, the control circuit may further receive the page selection command PSLTCMD before the control circuit receives the read command PRDCMD-1, but the example embodiments are not limited thereto.

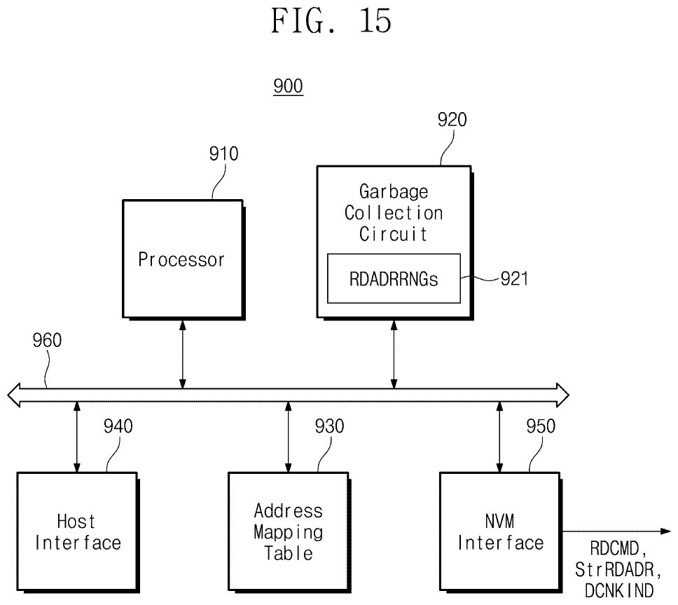

FIG. 15 is a block diagram illustrating at least one example embodiment of a memory controller communicating with a nonvolatile memory device of FIG. 1, but the example embodiments are not limited thereto.

Referring to FIG. 1 and FIG. 15, a memory controller 900 may correspond to the memory controller 100 of FIG. 1, but is not limited thereto.

The memory controller 900 may include at least one processor 910, a garbage collection circuit 920, an address mapping table 930, a host interface 940, an NVM interface 950, and/or at least one bus 960, etc., but is not limited thereto. The garbage collection circuit 920 may manage a plurality of read address ranges RDADRRNGs 921 described above with reference to FIG. 1 and FIG. 4, but the example embodiments are not limited thereto. According to some example embodiments, one or more of the at least one processor 910, the garbage collection circuit 920, the address mapping table 930, the host interface 940, the NVM interface 950, and/or the at least one bus 960, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The processor 910 may generally control the components 920, 930, 940, 950, and/or 960 of the memory controller 900, but is not limited thereto. The bus 960 may perform communication between the components 910, 920, 930, 940, and/or 950 of the memory controller 900, etc., but is not limited thereto.

The garbage collection circuit 920 may perform the garbage collection on the memory cell array (e.g., 330 of FIG. 1) of the nonvolatile memory device (e.g., 300 of FIG. 1) by using the address mapping table 930. For example, the garbage collection may be performed to secure and/or generate free blocks in the memory cell array by deallocating erased blocks in the memory cell array. In the process of performing the garbage collection, the garbage collection circuit 920 may generate address ranges for accessing memory cells targeted for garbage collection. The generated address ranges may be managed as a plurality of read address ranges 921. In this case, the plurality of read address ranges 921 may be continuous or discontinuous in an address space of the memory cell array. When the plurality of read address ranges 921 are continuous in the process of performing the garbage collection, data chunks output from the page buffer circuit of the nonvolatile memory device may be continuous in latches of the page buffer circuit, and when the plurality of read address ranges 921 are discontinuous, they may be discontinuous in latches of the page buffer circuit. In this case, according to some example embodiments of the inventive concepts described above with reference to FIG. 1 to FIG. 14, the nonvolatile memory device may output and/or continuously output a plurality of target data in units of data chunk based on the data chunk indicator.

In at least one example embodiment, the memory controller 900 may output the read command RDCMD, the start read address StrRDADR, and/or the data chunk indicator DCNKIND described above with reference to FIG. 1 to the nonvolatile memory device through the NVM interface 950, but the example embodiments are not limited thereto.

In other example embodiments, the read command RDCMD, the start read address StrRDADR, and/or the data chunk indicator DCNKIND may be transmitted from an external host device via the host interface 940. For example, the memory controller 900 may further include an error correction code (ECC) circuit which performs error correction on data to enhance and/or increase the reliability of data stored in the nonvolatile memory device. The ECC circuit may generate parity bits for data, and the memory controller 900 may store the parity bits in separate regions of the nonvolatile memory device. In this case, the plurality of read address ranges 921 associated with the parity bits may be discontinuous similar to the case described above with reference to FIG. 15, and according to some example embodiments of the inventive concepts, the nonvolatile memory device may output and/or continuously output a plurality of target data in units of data chunk based on a data chunk indicator.

FIG. 16 is a flowchart illustrating an operating method of a nonvolatile memory device according to at least one example embodiment of the inventive concepts.

Referring to FIG. 1, FIG. 5, and FIG. 16, the control circuit 310 may receive the read command RDCMD, the start read address StrRDADR, and/or the data chunk indicator DCNKIND (S100). The memory cell array 330 may output the first page data PGDAT1 including the plurality of first data chunks, e.g., DCNK11, DCNK12, DCNK13, and the like, based on the start row address StrRA (S300). The page buffer circuit 350 may output one or more (e.g., DCNKa, . . . ) of the plurality of first data chunks DCNK11, DCNK12, DCNK13, and the like, based on the data chunk indicator DCNKIND (S500).

Before operation S100 is performed, the control circuit 310 may receive a chunk size indicator which indicates a size of the data chunk which may be some or all of page data and is a unit of a set of data output from the page data circuit (S50).

In at least one example embodiment, before the control circuit 310 receives a read command (e.g., RDCMD in FIG. 1), the control circuit 310 may receive the chunk size indicator indicating the size of each of the plurality of first data chunks (e.g., DCNK11, DCNK12, DCNK13, and the like in FIG. 1).

For example, operation S50 may be an optional operation, e.g., may not be performed every time operation S100 is performed, and for example, may be performed one-time or may be performed less times than the number of times S100 is performed. For example, the control circuit 310 may receive the chunk size indicator at the time of shipping, initializing, and/or powering on the nonvolatile memory device (e.g., 300 of FIG. 1, 530 of FIG. 6, 700 of FIG. 7, etc.). The chunk size indicator may be received from an external host device and/or a memory controller controlling the nonvolatile memory device, and may be temporarily and/or non-temporarily stored in the nonvolatile memory device and/or the memory controller. For example, when the chunk size indicator is stored in the nonvolatile memory device, the chunk size indicator may be stored in a separate area within the control circuit and/or the memory cell array of the nonvolatile memory device, and when the chunk size indicator is stored in the memory controller, it may be stored in a buffer memory in the memory controller, but the example embodiments are not limited thereto.

As described above with reference to FIG. 1, one data chunk may be a set of data defined by dividing page data evenly or unevenly (e.g., evenly dividing the data size of a page of data, or unevenly dividing the data size of a page of data), and the chunk size indicator may be transmitted from the memory controller to the nonvolatile memory device before S100. Regardless of whether the sizes of data chunks included in one page data are equal or not, some example embodiments of the inventive concepts may be performed based on the data chunk indicator DCNKIND described above with reference to FIG. 1, FIG. 12A, and FIG. 12B, but is not limited thereto.

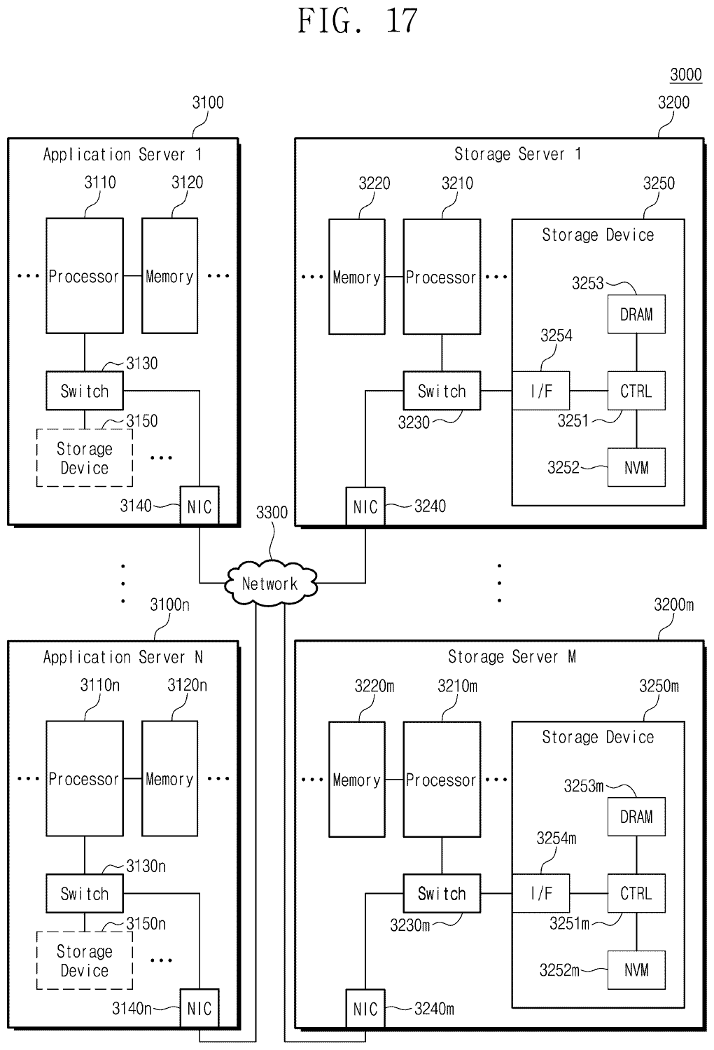

FIG. 17 is a diagram illustrating a data center including the memory system according to at least one example embodiment of the inventive concepts.

Referring to FIG. 17, the data center 3000 may be a facility that collects various types and/or pieces of data and/or provides services, and may be referred to as a data storage center, etc. For example, the data center 3000 may be a system for operating a search engine and/or a database, and may be a computing system used by companies, such as banks, etc., and/or government agencies, etc. The data center 3000 may include application servers 3100 to 3100n and storage servers 3200 to 3200m. The number of application servers 3100 to 3100n and the number of storage servers 3200 to 3200m may vary. The number of application servers 3100 to 3100n may be different from the number of storage servers 3200 to 3200m.

The application server 3100 and/or the storage server 3200 may include at least one of processors 3110 and 3210 and memories 3120 and 3220, etc., but the example embodiments are not limited thereto. The storage server 3200 will now be described as an example. The processor 3210 (e.g., processing circuitry, etc.) may control all operations of the storage server 3200, access the memory 3220, and/or execute instructions and/or data loaded in the memory 3220, etc., but is not limited thereto. The memory 3220 may be, e.g., a double-data-rate synchronous DRAM (DDR SDRAM), a high-bandwidth memory (HBM), a hybrid memory cube (HMC), a dual in-line memory module (DIMM), Optane DIMM, and/or a non-volatile DIMM (NVMDIMM), but the example embodiments are not limited thereto. In some example embodiments, the numbers of processors 3210 and/or memories 3220 included in the storage server 3200 may be variously selected. In at least one example embodiment, the processor 3210 and the memory 3220 may provide a processor-memory pair. In at least one example embodiment, the number of processors 3210 may be different from the number of memories 3220. The processor 3210 may be one or more processors, and may include a single-core processor and/or a multi-core processor. The above description of the storage server 3200 may be similarly applied to the application server 3100. In some example embodiments, the application server 3100 may not include a storage device 3150. The storage server 3200 may include at least one storage device 3250. The number of storage devices 3250 included in the storage server 3200 may be variously selected according to some example embodiments.

The application servers 3100 to 3100n may communicate with the storage servers 3200 to 3200m through at least one network 3300. The network 3300 may be a wired network implemented using, e.g., a fiber channel (FC) and/or Ethernet, etc., but is not limited thereto, and/or the network 3300 may be a wireless network, such as a WiFi network, a cellular network (e.g., 4G LTE network, 5G NR network, a 6G network, etc.), a satellite network, etc., but the example embodiments are not limited thereto. In the case where the network 3300 is implemented using FC, the FC may be a medium used for relatively high-speed data transmission and may use an optical switch with high performance and/or high availability, etc., but the example embodiments are not limited thereto. The storage servers 3200 to 3200m may be provided as file storages, block storages, and/or object storages according to an access method of the network 3300, etc.

In at least one example embodiment, the network 3300 may be a storage-dedicated network, such as a storage area network (SAN), etc. For example, the SAN may be an FC-SAN, which uses an FC network and is implemented according to an FC protocol (FCP), but is not limited thereto. As another example, the SAN may be an Internet protocol (IP)-SAN, which uses a transmission control protocol (TCP)/IP network and is implemented according to a SCSI over TCP/IP or Internet SCSI (iSCSI) protocol, but the example embodiments are not limited thereto. In another example embodiment, the network 3300 may be a general network, such as a TCP/IP network, etc. For example, the network 3300 may be implemented according to a protocol, such as FC over Ethernet (FCOE), network attached storage (NAS), and/or NVMe over Fabrics (NVMe-oF), etc.

Hereinafter, the application server 3100 and the storage server 3200 will mainly be described. A description of the application server 3100 may be applied to another application server 3100n, and/or a description of the storage server 3200 may be applied to another storage server 3200m, etc.

The application server 3100 may store data, which was requested by a user and/or at least one client, in one or more of the storage servers 3200 to 3200m through the network 3300. Also, the application server 3100 may obtain data, which was requested by the user and/or the client to be read from one or more of the storage servers 3200 to 3200m through the network 3300. For example, the application server 3100 may be implemented as a web server, a file server, and/or a database management system (DBMS), etc.

The application server 3100 may access a memory 3120n and/or a storage device 3150n, which is included in another application server 3100n, through the network 3300. Additionally or alternatively, the application server 3100 may access memories 3220 to 3220m and/or storage devices 3250 to 3250m, which are included in the storage servers 3200 to 3200m, through the network 3300. Thus, the application server 3100 may perform various operations on data stored in application servers 3100 to 3100n and/or the storage servers 3200 to 3200m. For example, the application server 3100 may execute an instruction for moving and/or copying data between the application servers 3100 to 3100n and/or the storage servers 3200 to 3200m. In this case, the data may be moved from the storage devices 3250 to 3250m of the storage servers 3200 to 3200m to the memories 3120 to 3120n of the application servers 3100 to 3100n directly and/or through the memories 3220 to 3220m of the storage servers 3200 to 3200m. The data moved through the network 3300 may be data encrypted for security and/or privacy, etc.

The storage server 3200 will now be described as an example. An interface 3254 may provide physical connection between at least one processor 3210 and at least one controller 3251 and a physical connection between at least one network interface card (NIC) 3240 and the controller 3251. For example, the interface 3254 may be implemented using, e.g., a direct attached storage (DAS) scheme in which the storage device 3250 is directly connected with at least one dedicated cable, etc. For example, the interface 3254 may be implemented by using various interface schemes, such as ATA, SATA, e-SATA, an SCSI, SAS, PCI, PCIe, NVMe, IEEE 1394, a USB interface, an SD card interface, an MMC interface, an eMMC interface, a UFS interface, an eUFS interface, and/or a CF card interface, but is not limited thereto.

The storage server 3200 may further include at least one switch 3230 and/or the NIC (Network InterConnect) 3240, etc. The switch 3230 may selectively connect the processor 3210 to the storage device 3250 and/or selectively connect the NIC 3240 to the storage device 3250 via the control of the processor 3210.

In at least one example embodiment, the NIC 3240 may include at least one network interface card and/or at least one network adaptor, etc. The NIC 3240 may be connected to the network 3300 by a wired interface, a wireless interface, a Bluetooth interface, and/or an optical interface, etc., but is not limited thereto. The NIC 3240 may include an internal memory, a digital signal processor (DSP), and/or a host bus interface and be connected to the processor 3210 and/or the switch 3230 through the host bus interface. The host bus interface may be implemented as one of the above-described examples of the interface 3254, but is not limited thereto. In at least one example embodiment, the NIC 3240 may be integrated with at least one of the processor 3210, the switch 3230, and/or the storage device 3250, etc.

In the storage servers 3200 to 3200m and/or the application servers 3100 to 3100n, at least one processor may transmit at least one command to storage devices 3150 to 3150n and/or 3250 to 3250m and/or the memories 3120 to 3120n and/or 3220 to 3220m to program and/or read data, etc. In this case, the data may be data of which an error is corrected by an ECC engine, but is not limited thereto. The data may be data on which a data bus inversion (DBI) operation and/or a data masking (DM) operation is performed, and may include cyclic redundancy code (CRC) information, but the example embodiments are not limited thereto. The data may be data encrypted for security and/or privacy, etc.

Storage devices 3150 to 3150n and 3250 to 3250m may transmit at least one control signal and/or a command/address signal to NAND flash memory devices 3252 to 3252m in response to at least one read command received from the processor, but is not limited thereto. Thus, when data is read from the NAND flash memory devices 3252 to 3252m, a read enable (RE) signal may be input as a data output control signal, and thus, the data may be output to a DQ bus. A data strobe signal DQS may be generated using the RE signal. The command and the address signal may be latched in a page buffer depending on a rising edge and/or falling edge of a write enable (WE) signal.

The controller 3251 may control all operations of the storage device 3250. In at least one example embodiment, the controller 3251 may include SRAM, but is not limited thereto. The controller 3251 may write data to the NAND flash memory device 3252 in response to a write command and/or read data from the NAND flash memory device 3252 in response to a read command, etc. For example, the write command and/or the read command may be provided from the processor 3210 of the storage server 3200, the processor 3210m of another storage server 3200m, and/or the processors 3110 and 3110n of the application servers 3100 and 3100n. DRAM 3253 may temporarily store (and/or buffer) data to be written to the NAND flash memory device 3252 and/or data read from the NAND flash memory device 3252. Also, the DRAM 3253 may store metadata, etc. Here, the metadata may be user data and/or data generated by the controller 3251 to manage the NAND flash memory device 3252, but is not limited thereto. The storage device 3250 may include a secure element (SE) for security and/or privacy, etc. Some or all of the storage devices 3150 to 3150n and 3250 to 3250m may be a memory system according to some example embodiments of the inventive concepts. Some or all of the application servers 3100 to 3100n may be the host devices referred to in the process of describing the memory system according to one or more example embodiments of the inventive concepts. However, the example embodiments of the inventive concepts are not limited thereto. Accordingly, some or all of the storage devices 3150 to 3150n and 3250 to 3250m may efficiently process at least one access request from a first application processor among the application servers 3100 to 3100n and at least one key change request from a second application processor among the application servers 3100 to 3100n, etc., but are not limited thereto.

Each of the storage devices 3250 to 3250m may include a non-volatile memory device according to one or more of the example embodiments of the inventive concepts. The NAND flash memory devices 3252 to 3252m may correspond to the non-volatile memory devices according to one or more of the example embodiments of the inventive concepts described above with reference to FIG. 1 to FIG. 16. Thus, the NAND flash memory devices 3252 to 3252m may improve the input/output performance of the NAND flash memory devices 2352 to 2352m by decreasing and/or preventing intervention of additional signals.

As described above, the nonvolatile memory device according to one or more of the example embodiments of the inventive concepts may output and/or continuously output a plurality of target data targeted for a data read operation in units of data chunks based on the data chunk indicator, and the target data may be a part of or all of the page data. In other words, the maximum size of a data chunk may be less than or equal to a maximum size of a page of data. Thus, additional signals (e.g., additional commands and/or additional addresses, etc.) need not be generated, issued, intervened (and/or applied) between one data chunk output from the nonvolatile memory device and another data chunk. The nonvolatile memory device may decrease, prevent, and/or remove intervention of the additional signals, and thus the input/output performance of the nonvolatile memory device and/or a memory system may be improved.

The above description is of specific example embodiments of the inventive concepts. However, the inventive concepts will include not only the above-described example embodiments, but also example embodiments changes or modifications thereto. In addition, the example embodiments of the inventive concepts will also include technologies which may be easily modified and implemented by using one or more example embodiments. Therefore, the scope of the inventive concepts should not be limited to the above-described example embodiments, but should be determined not only by the scope of the claims to be described later but also by those equivalent to the claims of the inventive concepts.

While various example embodiments of the inventive concepts have been described, it will be apparent to those of ordinary skill in the art that various changes and modifications may be made thereto without departing from the spirit and scope of the inventive concepts as set forth in the following claims.

What is claimed is:

1. A nonvolatile memory device comprising:
processing circuitry configured to receive a read command, a start read address, and a data chunk indicator, the read command including a page read command and a data read command, and the start read address including a start row address and a start column address;
a memory cell array configured to output first page data based on the start row address, the first page data including a plurality of first data chunks; and
the processing circuitry further configured to output one or more of the plurality of first data chunks based on the data chunk indicator.

2. The nonvolatile memory device of claim 1, wherein
the plurality of first data chunks correspond to a plurality of read address ranges, respectively; and
the processing circuitry is further configured to continuously output two or more of the plurality of first data chunks.

3. The nonvolatile memory device of claim 2, wherein the plurality of read address ranges include two or more discontinuous address ranges of the memory cell array.

4. The nonvolatile memory device of claim 1, wherein the data chunk indicator includes binary data indicating one or more of the plurality of first data chunks.

5. The nonvolatile memory device of claim 4, wherein
a number of the plurality of first data chunks is N, wherein N is an integer of 2 or more; and
the data chunk indicator has a size of N-bits.

6. The nonvolatile memory device of claim 1, wherein the processing circuitry is further configured to:
receive the page read command and the start read address; and
receive the data read command and the data chunk indicator.

7. The nonvolatile memory device of claim 6, wherein
the page read command includes a first read command and a second read command; and
the data read command includes a third read command and a fourth read command.

8. The nonvolatile memory device of claim 7, wherein the processing circuitry is further configured to:
sequentially receive the third read command, the data chunk indicator, and the fourth read command.

9. The nonvolatile memory device of claim 7, wherein the processing circuitry is further configured to:
sequentially receive the first read command, the start read address, the second read command, the third read command, the data chunk indicator, and the fourth read command; and
in response to a desired time period elapsing from a time the nonvolatile memory device received the fourth read command,
sequentially output two or more of the plurality of first data chunks.

10. The nonvolatile memory device of claim 1, wherein, before the read command is received, the processing circuitry is further configured to:
receive a chunk size indicator indicating a size of each of the plurality of first data chunks.

11. The nonvolatile memory device of claim 10, wherein, in response to the nonvolatile memory device being initialized or powered on, the processing circuitry is further configured to:
receive the chunk size indicator; and
store the chunk size indicator.

12. The nonvolatile memory device of claim 1, wherein the processing circuitry is further configured to:
receive a read enable signal which toggles based on a size of each of the plurality of first data chunks; and
generate a data strobe signal which toggles based on the read enable signal.

13. The nonvolatile memory device of claim 12, wherein the processing circuitry is further configured to:
output one or more of the plurality of first data chunks based on the data chunk indicator and the data strobe signal.

14. The nonvolatile memory device of claim 1, wherein
the memory cell array is configured to output block data or plane data based on the start row address, the block data including a plurality of first block data chunks, and the plane data including a plurality of first plane data chunks; and
the processing circuitry is further configured to sequentially output two or more of the plurality of first block data chunks or two or more of the plurality of first plane data chunks based on the data chunk indicator.

15. A method of operating a nonvolatile memory device, the method comprising:
receiving a read command, a start read address, and a data chunk indicator, the read command including a page read command and a data read command, and the start read address including a start row address and a start column address;
outputting first page data based on the start row address, the first page data including a plurality of first data chunks; and
outputting one or more of the plurality of first data chunks based on the data chunk indicator.

16. The method of claim 15, wherein the receiving of the read command, the start read address, and the data chunk indicator includes:
receiving the page read command and the start read address; and
receiving the data read command and the data chunk indicator.

17. The method of claim 16, wherein
the page read command includes a first read command and a second read command; and
the data read command includes a third read command and a fourth read command.

18. The method of claim 17, wherein
the receiving the page read command and the start read address includes sequentially receiving the first read command, the start read address, and the second read command; and
the receiving the read command and the data chunk indicator includes sequentially receiving the third read command, the data chunk indicator, and the fourth read command.

19. The method of claim 15, wherein the outputting one or more of the plurality of first data chunks includes continuously outputting two or more of the plurality of first data chunks indicated by the data chunk indicator.

20. A memory system comprising:
a memory controller configured to output a read command, a start read address, and a data chunk indicator, the read command including a page read command and a data read command, and the start read address including a start row address and a start column address; and
a nonvolatile memory device configured to operate based on the read command, the start read address, and the data chunk indicator,
the nonvolatile memory device including,
a memory cell array configured to output first page data based on the start row address, the first page data including a plurality of first data chunks, and
a page buffer circuit configured to continuously output two or more of the plurality of first data chunks based on the data chunk indicator.
